(19) United States
(12) Patent Application Publication
(10) Pub. No.: US 2015/0241780 A1
(43) Pub. Date: Aug. 27, 2015

(54) METHODS OF FORMING INSULATION LAYER STRUCTURES AND METHODS OF MANUFACTURING METAL INTERCONNECTIONS

(71) Applicant: SAMSUNG ELECTRONICS CO., LTD., Suwon-Si (KR)

(72) Inventors: Kyeng-Min PARK, Seoul (KR); Jin-Ho KIM, Hwaseong-si (KR)

(21) Appl. No.: 14/607,252

(22) Filed: Jan. 28, 2015

(30) Foreign Application Priority Data
Feb. 24, 2014 (KR) 10-2014-0021349

(51) Int. Cl. G03F 7/20; G03F 7/30

(52) U.S. Cl. CPC G03F 7/2022; G03F 7/30

(57) ABSTRACT

In a method of an insulation layer structure, a first photosensitive layer is formed on a substrate. The first photosensitive layer is partially exposed to form a first pattern and a second pattern. The second pattern includes silicon oxide. A second photosensitive layer is formed on the second pattern. The second photosensitive layer is partially exposed to form a third pattern and a fourth pattern. The fourth pattern includes silicon oxide. The first pattern is removed by performing a first developing process. The third pattern is removed by performing a second developing process.

### CLAIM OF PRIORITY

This application claims the benefit of priority under 35 USC §119 to Korean Patent Application No. 10-2014-0021349, filed on Feb. 24, 2014 in the Korean Intellectual Property Office (KIPO), the contents of which are herein incorporated by reference in their entirety.

### BACKGROUND

1. Field

Example embodiments relate to methods of forming insulation layer structures and methods of manufacturing metal interconnections.

2. Description of the Related Art

Recently, as the integration degree of a semiconductor device has increased, a method of forming a pattern has been developed. In a conventional method of manufacturing a semiconductor device, a damascene process is used to form a metal interconnection. In the damascene process, an insulation layer is formed on a substrate, an organic photoresist pattern is formed on the insulation layer, and the insulation layer is partially removed by an etching process to form an insulation layer structure. Then, a metal interconnection is formed to fill a contact hole or a trench of the insulation layer structure.

However, the organic photoresist pattern remains after performing the etching process. Therefore, a cleaning process or a strip process is required to remove the remaining organic photoresist pattern.

### SUMMARY

Some example embodiments provide methods of forming insulation layer structures without using an organic photoresist pattern.

Some example embodiments provide methods of manufacturing metal interconnections without using an organic photoresist pattern.

According to some example embodiments, there is provided a method of forming an insulation layer structure. In the method, a first photosensitive layer is formed on a substrate. The first photosensitive layer is partially exposed to form a first pattern and a second pattern. The second pattern includes silicon oxide. A second photosensitive layer is formed on the second pattern. The second photosensitive layer is partially exposed to form a third pattern and a fourth pattern. The fourth pattern includes silicon oxide. The first pattern is removed by performing a first developing process. The third pattern is removed by performing a second developing process.

In example embodiments, the performing a first developing process may occur before the forming a second photosensitive layer.

In example embodiments, the removing the first pattern may include forming a contact hole exposing a top surface of the substrate.

In example embodiments, the second photosensitive layer may fill the contact hole.

In example embodiments, the performing a first developing process may occur after the partially exposing the second photosensitive layer.

In example embodiments, the second photosensitive layer may be formed on the first pattern and the second pattern.

In example embodiments, the first developing process and the second developing process may be performed simultaneously.

In example embodiments, a third photosensitive layer may be formed on the fourth pattern. The third photosensitive layer may be partially exposed to form a fifth pattern and a sixth pattern. The sixth pattern may include silicon oxide.

In example embodiments, the first photosensitive layer and the second photosensitive layer may each include a silicon compound derivative, an organic solvent, and additives.

In example embodiments, the performing a first developing process and the performing a second developing process may include using a developing solution including an alkaline solution and an organic solvent.

In example embodiments, the fourth pattern may partially overlap the second pattern, and a planar area of the fourth pattern may be smaller than a planar area of the second pattern.

In example embodiments, the removing the first pattern may include forming a contact hole exposing a top surface of the substrate, and the removing the second pattern may include forming a trench in fluid communication with the contact hole.

In example embodiments, a first heat treatment process may be performed at a temperature between about 100° C. and about 500° C., after the partially exposing the first photosensitive layer. A second heat treatment process may be performed at a temperature between about 100° C. and about 500° C., after the partially exposing the second photosensitive layer.

According to other example embodiments, there is provided a method of manufacturing a metal interconnection. In the method, a first photosensitive layer is formed on a substrate. The first photosensitive layer is partially exposed to form a first pattern and a second pattern. The second pattern includes silicon oxide. A second photosensitive layer is formed on the second pattern. The second photosensitive layer is partially exposed to form a third pattern and a fourth pattern. The fourth pattern includes silicon oxide. The first pattern is removed to form a contact hole by performing a first developing process. The third pattern is removed to form a trench by performing a second developing process. The trench is in fluid communication with the contact hole. A conductive layer pattern is formed to fill the contact hole and the trench.

In example embodiments, a barrier layer pattern may be formed on inner walls of the contact hole and the trench, before the forming a conductive layer pattern.

According to yet other example embodiments, a method of forming an insulation layer structure includes forming a mold pattern of silicon oxide on a substrate by partially exposing photosensitive layers. The mold pattern includes a first mold layer pattern having at least one contact hole exposing a portion of the substrate, and a second mold layer pattern over the first mold layer pattern. The method further includes forming a filling pattern on the mold pattern, and removing the filling pattern by performing at least one developing process. The filling pattern is formed of unexposed portions of the photosensitive layers. The filling pattern includes a first filling pattern filling the at least one contact hole, and a second filling pattern filling a trench defined by the second mold layer pattern.

In example embodiments, the forming a mold pattern may include partially exposing a first photosensitive layer covering the substrate, and removing unexposed portions of the first photosensitive layer. The forming a filling pattern may include partially exposing a second photosensitive layer contacting the substrate and over the first mold layer pattern. The second mold layer pattern may be formed of exposed portions of the second photosensitive layer.

In example embodiments, the mold pattern may include a third mold layer pattern over the second mold layer pattern. The forming a mold pattern may further include partially exposing a third photosensitive layer contacting the substrate and over the second mold layer pattern. The third mold layer pattern may be formed of exposed portions of the third photosensitive layer.

In example embodiments, the forming a filling pattern may include partially exposing a first photosensitive layer over the first filling pattern. The second mold layer pattern may be formed of exposed portions of the first photosensitive layer.

In example embodiments, the mold pattern may further include a third mold layer pattern over the second mold layer pattern. The forming a filling pattern may further include partially exposing a second photosensitive layer over the second filling pattern and the second mold layer pattern. The third mold layer pattern may be formed of exposed portions of the second photosensitive layer.

According to example embodiments, the second pattern, the fourth pattern and the mold pattern may be formed without using an organic photoresist. Therefore, a cleaning process, a strip process and an ashing process for removing a remaining organic photoresist pattern may be omitted, and the processes for forming an insulation layer structure or a metal interconnect may be simplified.

### BRIEF DESCRIPTION OF THE DRAWINGS

Example embodiments will be more clearly understood from the following detailed description taken in conjunction with the accompanying drawings. FIGS. 1 to 27 represent non-limiting, example embodiments as described herein.

FIGS. 1 to 12 are plan views and cross-sectional views illustrating a method of forming a metal interconnection in accordance with some example embodiments;

FIGS. 13 to 19 are plan views and cross-sectional views illustrating a method of forming a metal interconnection in accordance with other example embodiments;

FIGS. 20 to 24 are cross-sectional views illustrating a method of forming a metal interconnection in accordance with further example embodiments; and

FIGS. 25 to 27 are cross-sectional views illustrating a method of forming a metal interconnection in accordance with yet other example embodiments.

### DETAILED DESCRIPTION OF EMAPLE EMBODIMENTS

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

Some example embodiments provide methods of forming insulation layer structures without using an organic photoresist pattern.

Some example embodiments provide methods of manufacturing metal interconnections without using an organic photoresist pattern.

FIGS. 1 to 12 are plan views and cross-sectional views of a method of forming a metal interconnection in accordance with some example embodiments.

Referring to FIG. 1, a first photosensitive layer 110 may be formed on a substrate 100.

The substrate 100 may include a semiconductor substrate such as a silicon substrate, germanium substrate or a silicon-germanium substrate, a substrate having a semiconductor layer and an insulation layer such as a silicon-on-insulator (SOI) substrate or a germanium-on-insulator (GOI) substrate, or a single crystalline metal oxide substrate.

The first photosensitive layer 110 may be formed by a spin coating process, or a deposition process, such as a chemical vapor deposition process. The first photosensitive layer 110 may be formed using a silicon compound derivative, an organic solvent, and additives. The first photosensitive layer 110 may mainly include a silicon compound derivative, so that the first photosensitive layer 110 may not be an organic photoresist pattern.

In example embodiments, the silicon compound derivative may include silane derivatives, siloxane derivatives, silazane derivatives, etc. The silicon compound derivative may form a silicon compound such as silicon oxide, when the silicon compound derivative is exposed to a light having a set (or, alternatively, predetermined) wavelength.

Further, the organic solvent may include propylene glycol monomethyl ether acetate (PGMEA), propylene glycol monomethyl ether (PGME), cyclohexanone, methanol, ethanol, and isopropyl alcohol, etc. The organic solvent may dissolve the silicon compound derivative, so that the spin coating process may be performed to form the first photosensitive layer 110 using the solution including the organic solvent and the silicon compound derivative.

The additives may include a photoactive acid generator (PAG), a photoactive radical generator (PRG), a thermalactive acid generator (TAG), etc. The additives may increase photosensitivity, or thermal sensitivity, of the first photosensitive layer 110. That is, when the first photosensitive layer 110 is exposed to the light having the set (or, alternatively, predetermined) wavelength, the additives may amplify a chemical reaction activated by the light. The additives may not be limited to the above materials, however the additives may include other materials that may improve photosensitivity, or thermal sensitivity, of the first photosensitive layer 110.

In example embodiments, the first photosensitive layer 110 may have a uniform desired thickness starting from a top surface of the substrate 100. For example, the first photosensitive layer 110 may have a thickness of about several nanometers to about several micrometers.

In other example embodiments, a semiconductor device may be formed in an upper portion of the substrate 100, or on the substrate 100. The semiconductor device may include a transistor, a capacitor, a wiring and/or an impurity region according to a semiconductor apparatus.

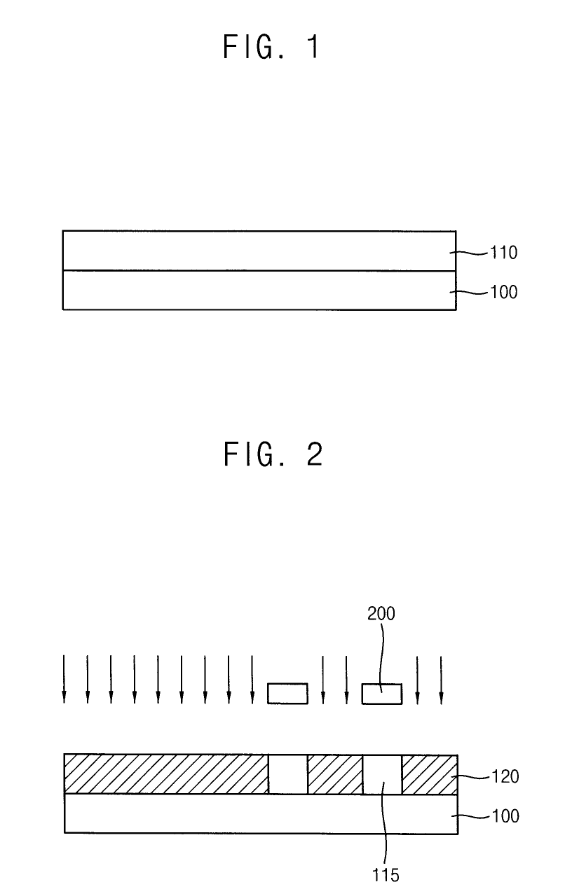

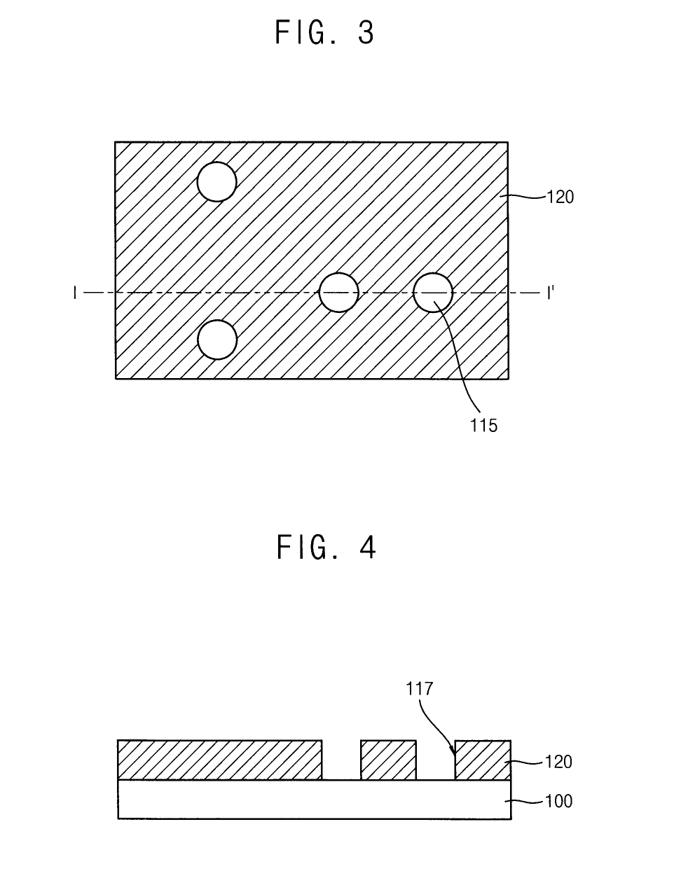

Referring to FIGS. 2 and 3, the first photosensitive layer 110 may be partially exposed to form a first pattern 115 and a second pattern 120.

The exposure process may use a first photo mask 200, such that a desired (or, alternatively, predetermined) portion of the first photosensitive layer 110 may be exposed. During the exposure process, an acid material is formed in the desired (or, alternatively, predetermined) portion of the first photosensitive layer 110, so that the acid material may cause a chemical reaction in which the silicon compound derivative is transferred into silicon oxide. Therefore, the desired (or, alternatively, predetermined) portion of the first photosensitive layer 110 may be defined as a second pattern 120 including silicon oxide, and a remaining portion of the first photosensitive layer 110 may be defined as a first pattern 115. In example embodiments, the second pattern 120 may essentially consist of silicon oxide.

In example embodiments, a heat treatment process (that is, a post exposure baking process) may be selectively performed, after the exposure process. The heat treatment process may be performed at a temperature of about 100° C. to about 500° C. Therefore, the heat treatment process may facilitate the chemical reaction caused by the exposure process, and may harden the second pattern 120 additionally. In other example embodiments, the heat treatment process may be omitted.

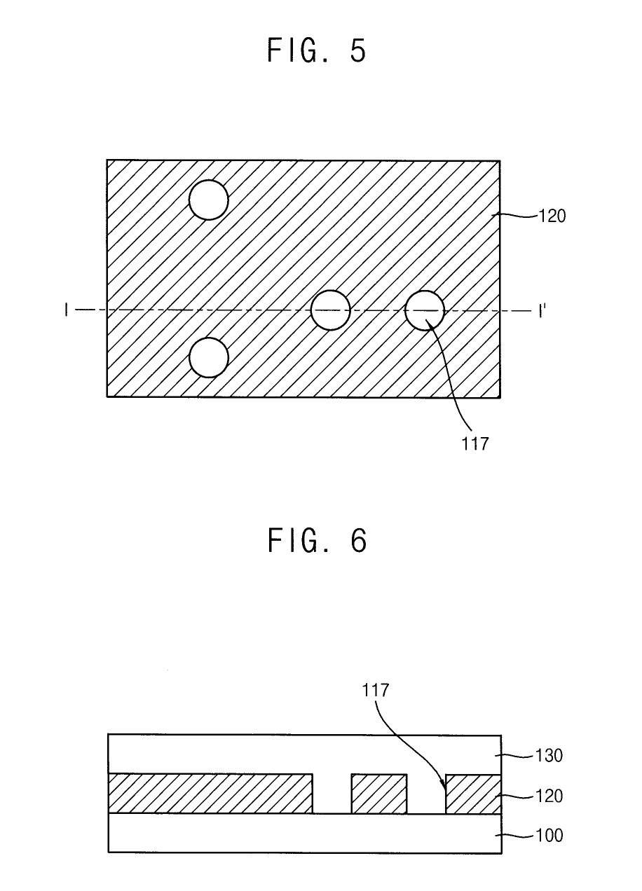

Referring to FIGS. 4 and 5, the first pattern 115 may be removed by a first developing process using a developing solution.

The developing solution may include an alkaline solution, an organic solvent and/or a mixture thereof.

In example embodiments, the alkaline solution may include a tetraalkylammonium hydroxide solution, the alkyl may be a saturated hydrocarbon, and the number of carbon atoms in the alkyl may be between 1 and 10. Particularly, the alkaline solution may include tetramethylammonium hydroxide (TMAH), and the number of carbon atoms in the alkyl may be 1. However, the alkaline solution may not be limited thereto, and the alkaline solution may include other chemical compound that may have an etch selectivity with respect to the first pattern 115 and the second pattern 120.

Further, the organic solvent may include propylene glycol monomethyl ether acetate (PGMEA), propylene glycol monomethyl ether (PGME), cyclohexanone, methanol, ethanol, and isoproplyl alcohol, etc. However, the organic solvent may not be limited thereto, and the organic solvent may include other chemical compounds that may have an identical function.

By performing the above the developing process, the first pattern 115 may be removed, and the second pattern 120 may remain on the substrate 100. In example embodiments, the first pattern 115 may be removed to form a contact hole 117 exposing a top surface of the substrate 100. In other example embodiments, the first pattern 115 may be removed to form a trench, or a recess, that may have a planar shape different from that of the contact hole 117.

In example embodiments, the second pattern 120 may be formed without using an organic photoresist. Therefore, a cleaning process, a strip process and an ashing process for removing a remaining organic photoresist pattern may be omitted, and the process for forming the second pattern 120 may be simplified.

Referring to FIG. 6, a second photosensitive layer 130 may be formed on the second pattern 120 to fill the contact hole 117.

The process for forming the second photosensitive layer 130 may be substantially the same as, or similar to, those described with reference to FIG. 1. That is, the second photosensitive layer 130 may be formed using a silicon compound derivative, an organic solvent, and additives.

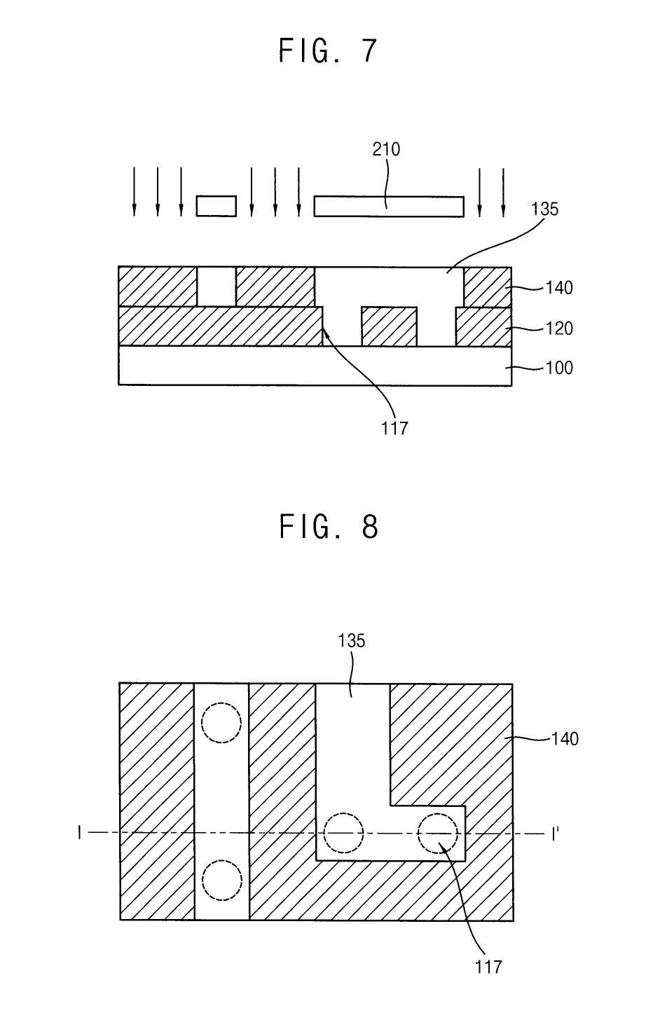

Referring to FIGS. 7 and 8, the second photosensitive layer 130 may be partially exposed to form a third pattern 135 and a fourth pattern 140.

A process for partially exposing the second photosensitive layer 130 by using a second photo mask 210 may be substantially the same as, or similar to, those described with reference to FIGS. 2 and 3.

However, the third pattern 135 and the fourth pattern 140 may have planar shapes that may be different from those of the first pattern 115 and the second pattern 120. In example embodiments, the third pattern 135 may overlap the contact hole 117 where the first pattern 115 was disposed (see FIG. 2), and a planar area of the third pattern 135 may be substantially greater than that of the first pattern 115. Further, the fourth pattern 140 may partially overlap the second pattern 120, and a planar area of the fourth pattern 140 may be substantially smaller than that of the second pattern 120.

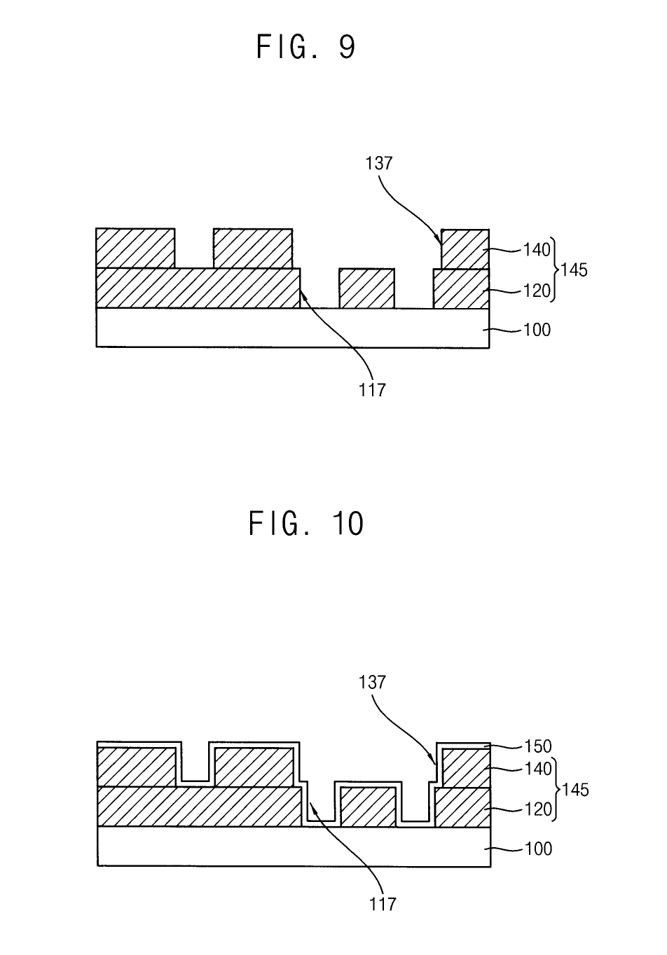

Referring to FIG. 9, the third pattern 135 may be removed by a second developing process using a developing solution.

The second developing process may be substantially the same as, or similar to, the second developing process described with reference to FIGS. 4 and 5. Therefore, the third pattern 135 may be removed from the substrate 100, and the fourth pattern 140 may remain on the second pattern 120. That is, the second pattern 120 and the fourth pattern 140 may constitute an insulation layer structure 140. The second pattern 120 and the fourth pattern 140 may have different planar shapes, so that the insulation layer structure 140 may have a three-dimensional shape including a stepped portion.

In example embodiments, the third pattern 135 may be removed to form a first trench 137 that may be in fluid communication with the contact hole 117, and may expose a top surface of the substrate 100. The contact hole 117 and the first trench 137 may have different planar shapes.

In other example embodiments, the third pattern 135 may be removed to form other contact holes, or a recess, that may have a planar shape different from that of the first trench 137.

According to example embodiments, the insulation layer structure 145 having a three-dimensional shape may be formed without performing an etching process using an organic photoresist. Therefore, a cleaning process, a strip process and an ashing process for removing a remaining organic photoresist pattern may be omitted, and the process for forming the insulation layer structure 145 may be simplified. Further, a first patterning process using the first photosensitive layer 110, and a second patterning process using the second photosensitive layer 130, may be performed sequentially, so that the insulation layer structure 145 having three-dimensional shape including the stepped portion may be formed.

Referring to FIG. 10, a barrier layer 150 may be formed on a top surface and a sidewall of the insulation layer structure 145 and the top surface of the substrate 100.

The barrier layer 150 may be formed by a deposition process using a metal such as titanium (Ti), tantalum (Ta), etc., or a metal nitride such as titanium nitride (TiN), tantalum nitride (TaN), etc. In example embodiments, the barrier layer 150 may be formed conformally on the top surface and the sidewall of the insulation layer structure 145 and the top surface of the substrate 100.

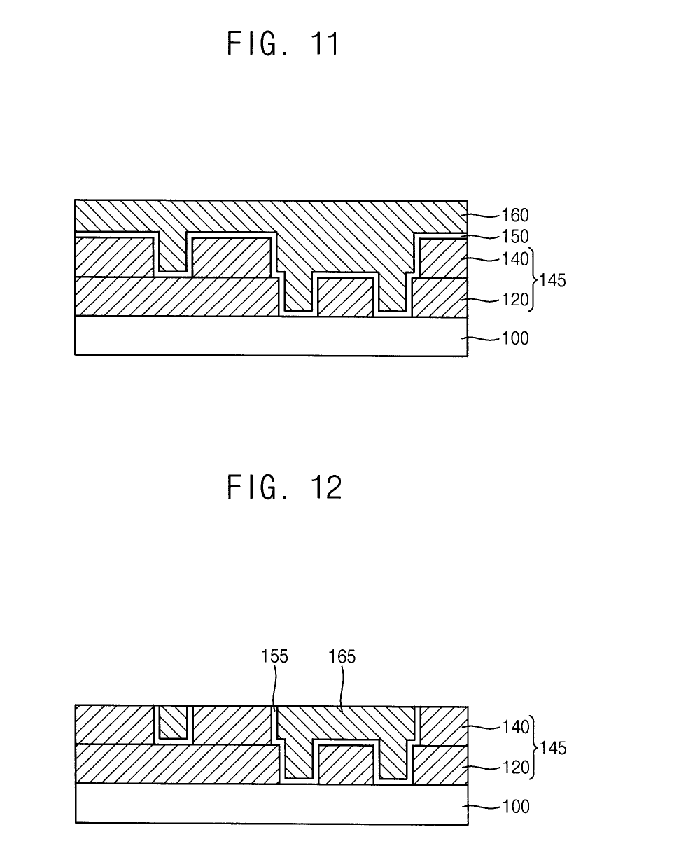

Referring to FIG. 11, a conductive layer 160 may be formed on the barrier layer 150.

The conductive layer 160 may be formed by a deposition process, an electroplating process, or a coating process, using aluminum (Al), tungsten (W), copper (Cu), silver (Ag), gold (Au), platinum (Pt), nickel (Ni), or an alloy thereof. Therefore, the conductive layer 160 may be formed to fill the first contact hole 117 and the first trench 137.

Referring to FIG. 12, upper portions of the barrier layer 150 and the conductive layer 160 may be removed to form a barrier layer pattern 155 and the conductive layer pattern 165.

The barrier layer 150 and the conductive layer 160 may be partially removed by a chemical mechanical planarization (CMP) process, or an etch-back process. For example, if the conductive layer 160 includes Al, W, Ag, etc., the upper portion of the conductive layer 160 may be removed by the etch-back process. Alternatively, if the conductive layer 160 includes Cu, the upper portion of the conductive layer 160 may be removed by the CMP process.

Accordingly, a metal interconnection including the barrier layer pattern 155 and the conductive layer pattern 165 may be formed without performing an etching process using an organic photoresist.

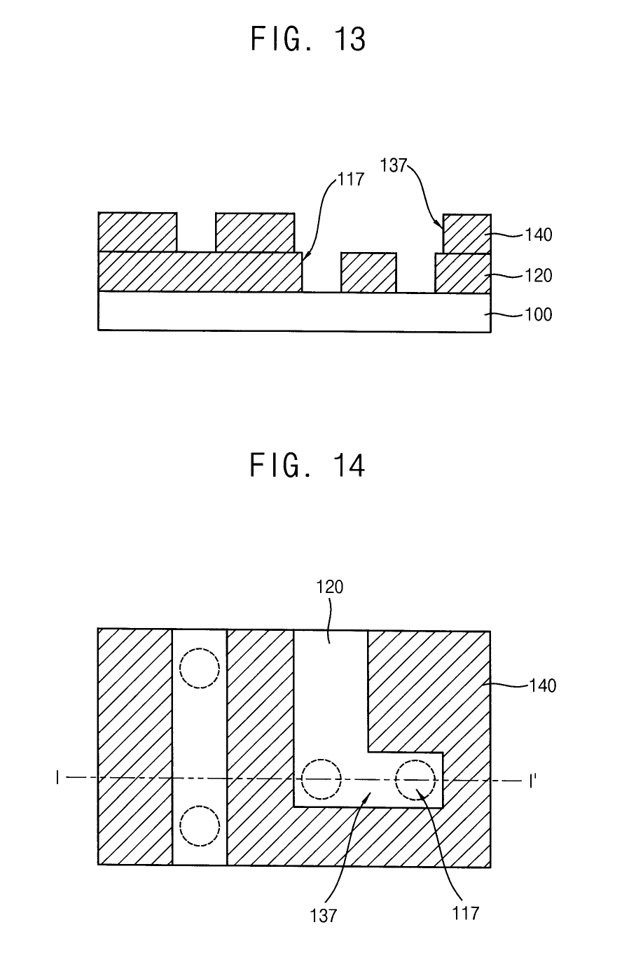

FIGS. 13 to 19 are plan views and cross-sectional views illustrating a method of forming a metal interconnection in accordance with other example embodiments.

Referring to FIGS. 13 and 14, a second pattern 120 and a fourth pattern 140 may be formed on the substrate 100 by performing processes that may be substantially the same as, or similar to, those described with reference to FIGS. 1 to 9.

That is, a first photosensitive layer may be formed on the substrate 100, and the first photosensitive layer may be partially exposed and developed to form the second pattern 120. Then, a second photosensitive layer may be formed on the second pattern 120 and the substrate 100, and then the second photosensitive layer may be partially exposed and developed to form the fourth pattern 140. Further, a contact hole 117 may be defined by a top surface of the substrate 100 and a sidewall of the second pattern 120, and a first trench 137 may be defined by a sidewall of the fourth pattern 140 and a top surface of the second pattern 120.

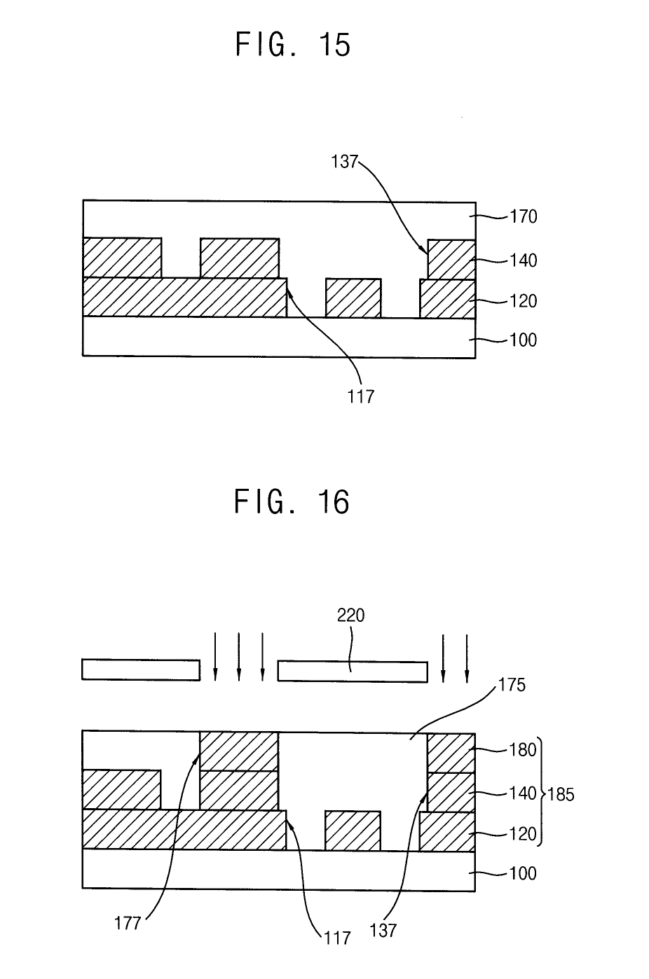

Referring to FIG. 15, a third photosensitive layer 170 may be formed on the second pattern 120 and the fourth pattern 140 to fill the contact hole 117 and the first trench 137.

Process for forming the third photosensitive layer 170 may be substantially the same as, or similar to, those described with reference to FIG. 1. That is, the third photosensitive layer 170 may be formed using a silicon compound derivative, an organic solvent, and additives.

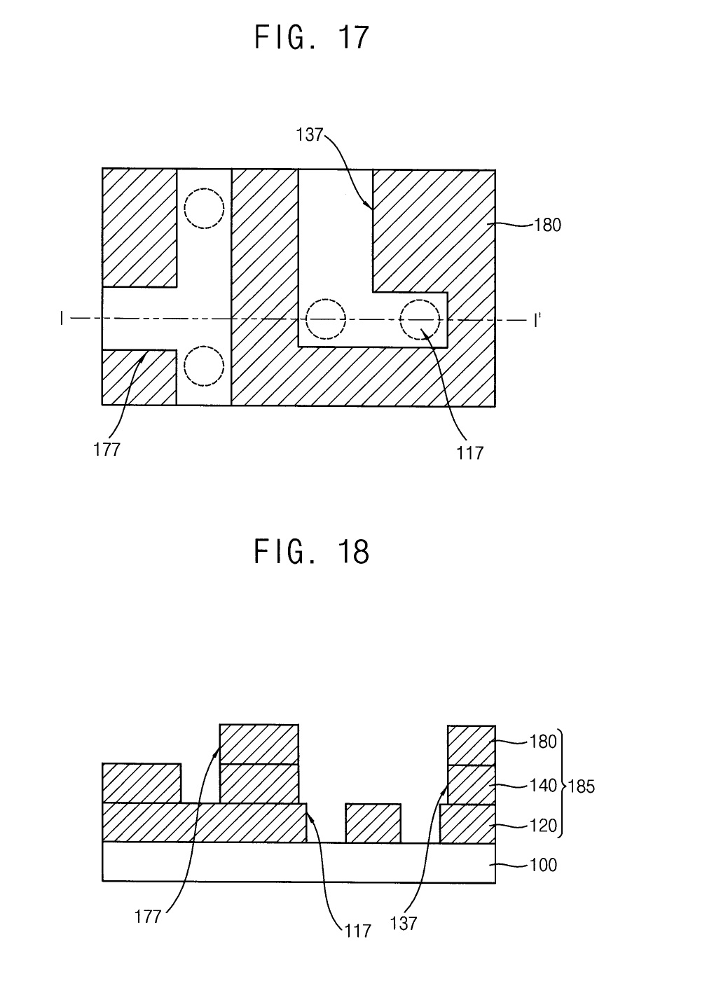

Referring to FIGS. 16 and 17, the third photosensitive layer 170 may be partially exposed to form a fifth pattern 175 and a sixth pattern 180.

However, the fifth pattern 175 and the sixth pattern 180 may have planar shapes that may be different from those of the third pattern 135 and the fourth pattern 140. In example embodiments, the fifth pattern 175 may overlap the first trench 137 where the third pattern 135 was disposed (see FIG. 7), and a planar area of the fifth pattern 175 may be substantially greater than that of the third pattern 135. Further, the sixth pattern 180 may partially overlap the fourth pattern 140, and a planar area of the sixth pattern 180 may be substantially smaller than that of the fourth pattern 140.

Referring to FIG. 18, the fifth pattern 175 may be removed by a third developing process using a developing solution.

The fifth pattern 175 may be removed from the substrate 100, and the sixth pattern 180 may remain on the fourth pattern 140. That is, the second pattern 120, the fourth pattern 140 and the sixth pattern 180 may constitute an insulation layer structure 185. The second pattern 120, the fourth pattern 140 and the sixth pattern 180 may have different planar shapes, so that the insulation layer structure 185 may have three-dimensional shape including at least one stepped portion.

Further, the contact hole 117 may be defined by a sidewall of the second pattern 120, the first trench 137 may be defined by a sidewall of the fourth pattern 140 and the second trench 177 may be defined by a sidewall of the sixth pattern 180.

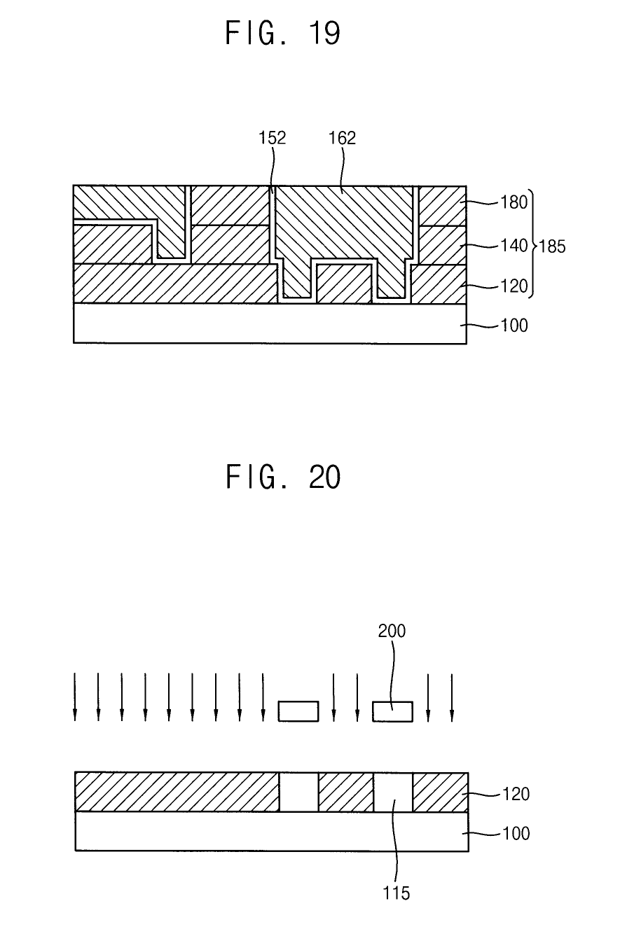

Referring to FIG. 19, a barrier layer pattern 152 and a conductive layer pattern 162 may be formed to fill the contact hole 117, the first trench 137 and the second trench 177. Processes for forming the barrier layer pattern 152 and the conductive layer pattern 162 may be substantially the same as, or similar to, those described with reference to FIGS. 10 to 12.

In example embodiments, the insulation layer structure 185 is illustrated to have three levels including the second pattern 120, the fourth pattern 140 and the sixth pattern 180, however the number of levels of the insulation layer structure 185 may not be limited thereto. For example, the number of levels of the insulation layer structure 185 may be between four and hundreds.

FIGS. 20 to 24 are cross-sectional views illustrating a method of forming a metal interconnection in accordance with further example embodiments.

Referring to FIG. 20, a first pattern 115 and a second pattern 120 may be formed on a substrate 100 by performing processes that may be substantially the same as, or similar to, those described with reference to FIGS. 1 to 3.

That is, a first photosensitive layer may be formed on the substrate 100, and the first photosensitive layer may be partially exposed by a first photo mask 200 to form the first pattern 115 and the second pattern 120.

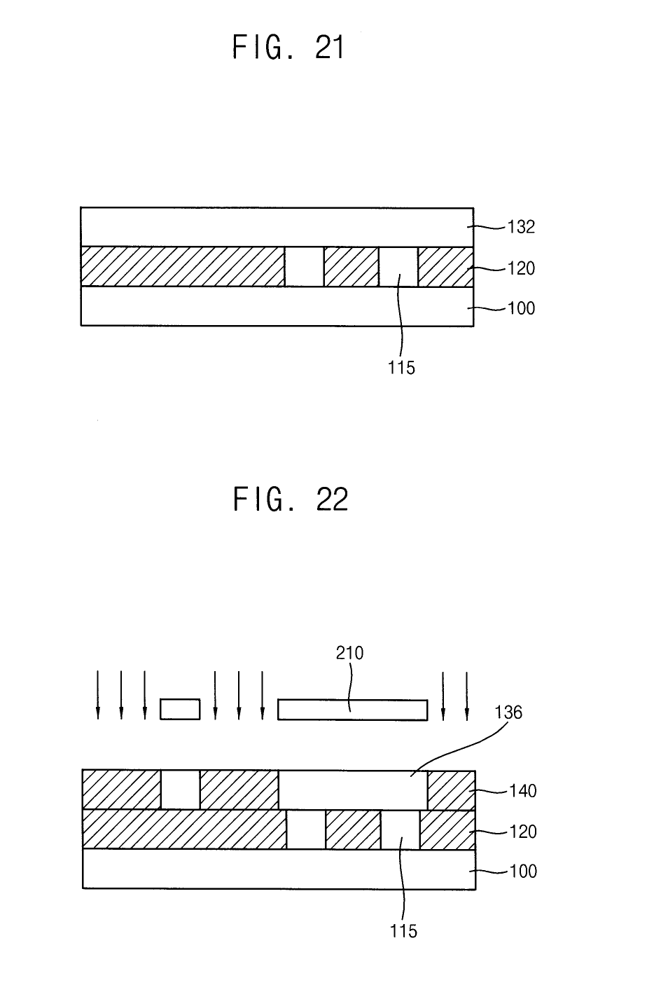

Referring to FIG. 21, a second photosensitive layer 132 may be formed on the first pattern 115 and the second pattern 120. The second photosensitive layer 132 may include a material substantially the same as, or similar to, those of the first photosensitive layer 110.

Referring to FIG. 22, a second photosensitive layer 132 may be partially exposed to form a third pattern 136 and a fourth pattern 140.

A process for partially exposing the second photosensitive layer 132 by using a second photo mask 210 may be substantially the same as, or similar to, those described with reference to FIGS. 2 and 3.

In example embodiments, the third pattern 136 may overlap the first pattern 115, and a planar area of the third pattern 136 may be substantially greater than that of the first pattern 115. Therefore, the first pattern 115 may not be exposed during the process for partially exposing the second photosensitive layer 132.

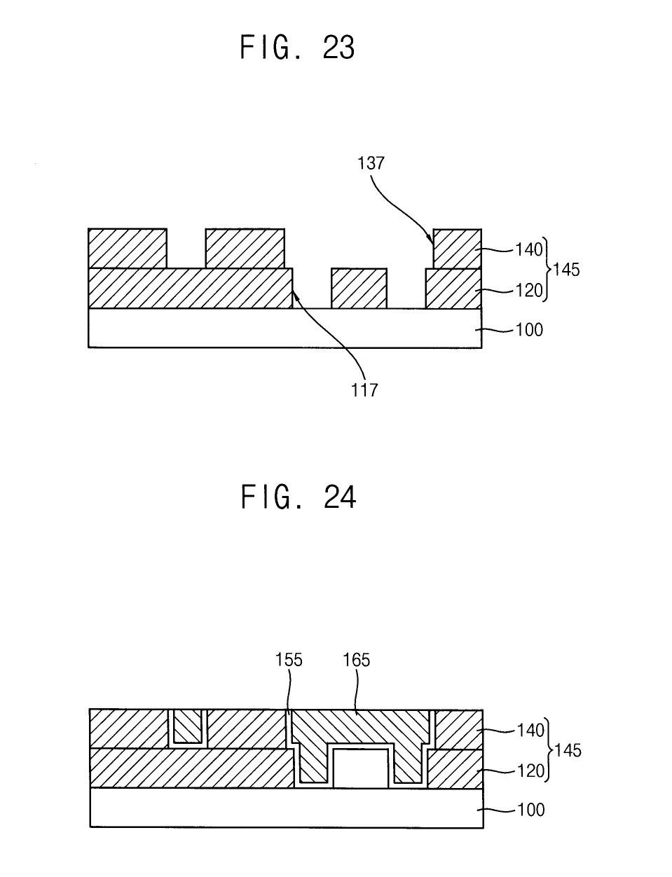

Referring to FIG. 23, the first pattern 115 and the third pattern 136 may be removed by a developing process using a developing solution. The developing solution may be substantially the same as the developing solution described with reference to FIGS. 4 and 5.

As the first pattern 115 is removed, a contact hole 117 may be defined by a sidewall of the second pattern 120 and a top surface of the substrate 100. Further, as the third pattern 136 is removed, a first trench 137 may be defined by a sidewall of the fourth pattern 140 and a top surface of the second pattern 136. In example embodiments, the first trench 137 may be in fluid communication with the contact hole 117, and may have a planar area substantially greater than that of the contact hole 117.

Referring to FIG. 24, a barrier layer pattern 155 and a conductive layer pattern 165 may be formed to fill the contact hole 117 and the first trench 137. Processes for forming the barrier layer pattern 155 and the conductive layer pattern 165 may be substantially the same as, or similar to, those described with reference to FIGS. 10 to 12.

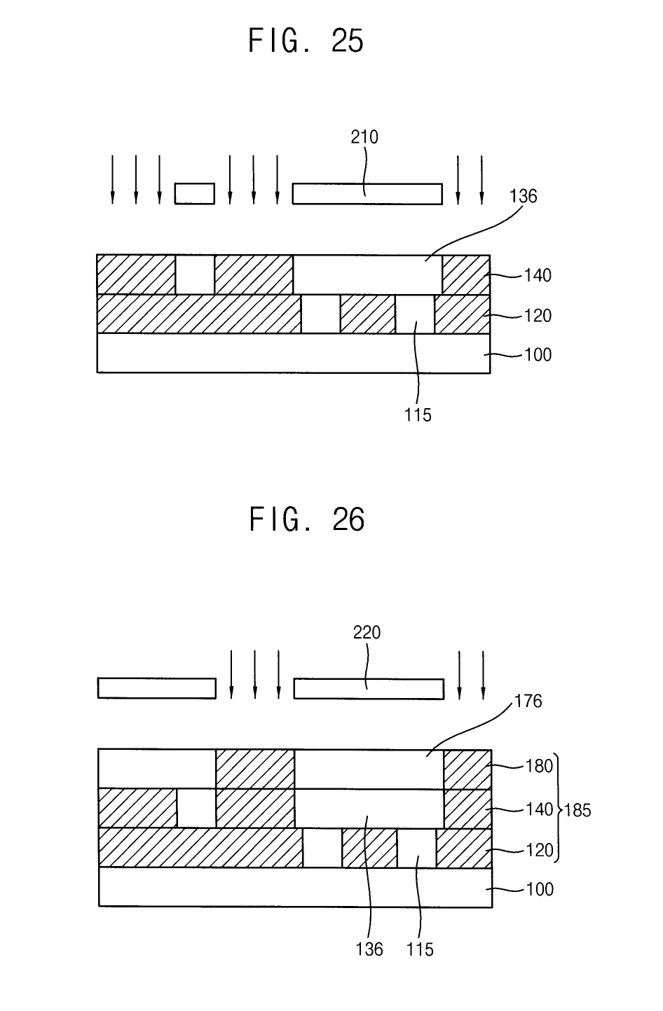

FIGS. 25 to 27 are cross-sectional views illustrating a method of forming a metal interconnection in accordance with yet other example embodiments.

Referring to FIG. 25, a first pattern 115, a second pattern 120, a third pattern 136 and a fourth pattern 140 may be formed on the substrate 100 by performing processes that may be substantially the same as, or similar to, those described with reference to FIGS. 20 to 22.

That is, a first photosensitive layer may be formed on the substrate 100, and the first photosensitive layer may be partially exposed to form the first pattern 115 and the second pattern 120. Then, a second photosensitive layer may be formed on the first pattern 115 and the second pattern 120, and then the second photosensitive layer may be partially exposed by a second photo mask 210 to form a third pattern 136 and a fourth pattern 140.

Referring to FIG. 26, a third photosensitive layer (not shown) may be formed on the third pattern 136 and the fourth pattern 140, and then third photosensitive layer may be partially exposed by a third photo mask 220 to form a fifth pattern 176 and a sixth pattern 180.

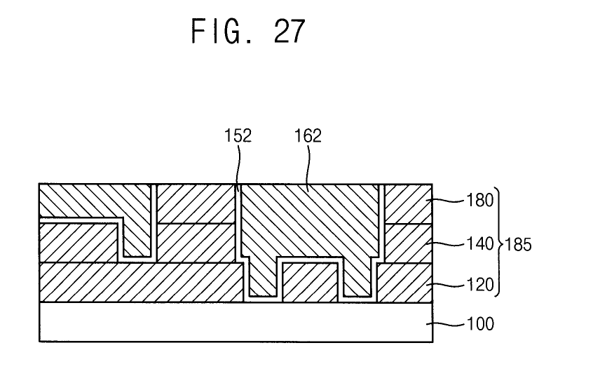

Referring to FIG. 27, the first pattern 115, the third pattern 136 and the fifth pattern 176 may be removed by a developing process, and then a barrier layer pattern 152 and a conductive layer pattern 162 may be formed to replace the first pattern 115, the third pattern 136 and the fifth pattern 176.

In example embodiments, the insulation layer structure 185 is illustrated to have three levels including the second pattern 120, the fourth pattern 140 and the sixth pattern 180, however the number of levels of the insulation layer structure 185 may not be limited thereto. For example, the number of levels of the insulation layer structure 185 may be between four and hundreds.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming an insulation layer structure, comprising:
forming a first photosensitive layer on a substrate;
partially exposing the first photosensitive layer to form a first pattern and a second pattern, the second pattern including silicon oxide;
forming a second photosensitive layer on the second pattern;
partially exposing the second photosensitive layer to form a third pattern and a fourth pattern, the fourth pattern including silicon oxide;
removing the first pattern by performing a first developing process; and
removing the third pattern by performing a second developing process.

2. The method of claim 1, wherein the performing a first developing process occurs before the forming a second photosensitive layer.

3. The method of claim 2, wherein the removing the first pattern includes forming a contact hole exposing a top surface of the substrate.

4. The method of claim 3, wherein the second photosensitive layer fills the contact hole.

5. The method of claim 1, wherein the performing a first developing process occurs after the partially exposing the second photosensitive layer.

6. The method of claim 5, wherein the second photosensitive layer is formed on the first pattern and the second pattern.

7. The method of claim 6, wherein the first developing process and the second developing process are performed simultaneously.

8. The method of claim 1, further comprising:
forming a third photosensitive layer on the fourth pattern; and
partially exposing the third photosensitive layer to form a fifth pattern and a sixth pattern, the sixth pattern including silicon oxide.

9. The method of claim 1, wherein the first photosensitive layer and the second photosensitive layer each include a silicon compound derivative, an organic solvent, and additives.

10. The method of claim 1, wherein the performing a first developing process and the performing a second developing process include using a developing solution, the developing solution including an alkaline solution and an organic solvent.

11. The method of claim 1, wherein the fourth pattern partially overlaps the second pattern, and
a planar area of the fourth pattern is smaller than a planar area of the second pattern.

12. The method of claim 1, wherein
the removing the first pattern includes forming a contact hole exposing a top surface of the substrate, and
the removing the second pattern includes forming a trench in fluid communication with the contact hole.

13. The method of claim 1, further comprising:
performing a first heat treatment process at a temperature between about 100° C. and about 500° C., after the partially exposing the first photosensitive layer; and
performing a second heat treatment process at a temperature between about 100° C. and about 500° C., after the partially exposing the second photosensitive layer.

14. A method of manufacturing a metal interconnection, comprising:
forming a first photosensitive layer on a substrate;
partially exposing the first photosensitive layer to form a first pattern and a second pattern, the second pattern including silicon oxide;
forming a second photosensitive layer on the second pattern;
partially exposing the second photosensitive layer to form a third pattern and a fourth pattern, the fourth pattern including silicon oxide;
removing the first pattern to form a contact hole by performing a first developing process;
removing the third pattern to form a trench by performing a second developing process, the trench being in fluid communication with the contact hole; and
forming a conductive layer pattern to fill the contact hole and the trench.

15. The method of claim 14, further comprising:
forming a barrier layer pattern on inner walls of the contact hole and the trench, before the forming a conductive layer pattern.

16. A method of forming an insulation layer structure, comprising:
forming a mold pattern of silicon oxide on a substrate by partially exposing photosensitive layers, the mold pattern including a first mold layer pattern having at least one contact hole exposing a portion of the substrate, and a second mold layer pattern over the first mold layer pattern;
forming a filling pattern on the mold pattern,
the filling pattern being formed of unexposed portions of the photosensitive layers, and
the filling pattern including a first filling pattern filling the at least one contact hole, and a second filling pattern filling a trench defined by the second mold layer pattern; and
removing the filling pattern by performing at least one developing process.

17. The method of claim 16, wherein
the forming a mold pattern includes partially exposing a first photosensitive layer covering the substrate, and removing unexposed portions of the first photosensitive layer, and
the forming a filling pattern includes partially exposing a second photosensitive layer contacting the substrate and over the first mold layer pattern, the second mold layer pattern being formed of exposed portions of the second photosensitive layer.

18. The method of claim 17, wherein
the mold pattern includes a third mold layer pattern over the second mold layer pattern, and the forming a mold pattern further includes partially exposing a third photosensitive layer contacting the substrate and over the second mold layer pattern, the third mold layer pattern being formed of exposed portions of the third photosensitive layer.

19. The method of claim 16, wherein the forming a filling pattern includes partially exposing a first photosensitive layer over the first filling pattern, the second mold layer pattern being formed of exposed portions of the first photosensitive layer.

20. The method of claim 19, wherein
the mold pattern further includes a third mold layer pattern over the second mold layer pattern, and
the forming a filling pattern further includes partially exposing a second photosensitive layer over the second filling pattern and the second mold layer pattern, the third mold layer pattern being formed of exposed portions of the second photosensitive layer.
